(19) United States
(12) Patent Application Publication
(10) Pub. No.: US 2025/0336875 A1
(43) Pub. Date: Oct. 30, 2025

(54) UNDERFILL FILM, SEMICONDUCTOR PACKAGE INCLUDING UNDERFILL FILM, AND MANUFACTURING METHOD THEREOF

(71) Applicant: Samsung Electronics Co., Ltd., Suwon-si (KR)

(72) Inventors: Seon Ho LEE, Suwon-si (KR); Wonkeun KIM, Suwon-si (KR)

(73) Assignee: Samsung Electronics Co., Ltd., Suwon-si (KR)

(21) Appl. No.: 18/913,510

(22) Filed: Oct. 11, 2024

(30) Foreign Application Priority Data
Apr. 25, 2024 (KR) 10-2024-0055687

(51) Int. Cl. H01L 23/00; H01L 25/18; H10B 80/00

(52) U.S. Cl. CPC H01L 24/29; H01L 24/16; H01L 24/32; H01L 24/73; H01L 24/83; H01L 24/96; H01L 24/97; H01L 25/18; H01L 2224/16148; H01L 2224/29082; H01L 2224/2929; H01L 2224/29387; H01L 2224/32145; H01L 2224/73204; H01L 2224/83002; H01L 2224/96; H01L 2224/97; H01L 2225/06513; H01L 2225/06544; H01L 2924/14361; H10B 80/00

(57) ABSTRACT

An underfill film may include a first film layer having a first dielectric constant, and a second film layer on the first film layer and having a second dielectric constant, where the second dielectric constant is higher than the first dielectric constant.

### CROSS-REFERENCE TO RELATED APPLICATION

This application claims priority to and the benefit of Korean Patent Application No. 10-2024-0055687 filed in the Korean Intellectual Property Office on Apr. 25, 2024, the entire contents of which are incorporated herein by reference.

### BACKGROUND

### (a) Field

The present inventive concepts relate to underfill films, semiconductor packages including an underfill film, and manufacturing methods for manufacturing underfill films and/or semiconductor packages including an underfill film.

### (b) Description of the Related Art

The semiconductor industry is pursuing to down-size, lighten, and thin the semiconductor packages mounted in electronic devices, while simultaneously pursuing higher speed, multifunction, and large capacity, in response to the demand for down-sizing and lightening of electronic devices. Therefore, the need for packaging technology that can store more data and transmit data at a faster rate is increasing, and as such packaging technology, a stacked semiconductor device (e.g., a high bandwidth memory (HBM)) formed by stacking a plurality of individual semiconductor dies is under development.

The stacked semiconductor device is manufactured by combining the same or different types of semiconductor dies, and what is important in combining the semiconductor dies is that the semiconductor dies must be combined with a high I/O density.

If the I/O density is increased to make the density of electric signal connections similar to the density of copper wires in the semiconductor front-end process, combining the same or different types of semiconductor chips in the semiconductor back-end process can yield results similar to those of a single semiconductor chip produced through the semiconductor front-end process.

To manufacture such a stacked semiconductor device, flip chip bonding technology may be applied to bond the semiconductor dies together. A stacked semiconductor device manufactured by using flip chip bonding technology may include micro-bumps for electrically connecting semiconductor dies, and an underfill film (non-conductive film (NCF)) disposed between the semiconductor dies and configured to protect the micro-bumps. The underfill film is made of a material that includes a thermosetting resin with added silica-based inorganic filler, or a thermosetting resin with added alumina-based inorganic filler.

### SUMMARY

A silica-based underfill film may have a low viscosity in its liquid state. Accordingly, the silica-based underfill film may form a fillet in which an underfill film protrudes outward between semiconductor dies stacked during the process of performing the bonding process. If the fillet is excessively formed, it may affect the structure of the stacked semiconductor device and may decrease the reliability of the stacked semiconductor device. In addition, due to its low viscosity in the liquid state, a silica-based underfill film may cause the solder of micro-bumps to flow during the bonding process, potentially leading to short circuits caused by the flowed solder. In addition, because the silica-based underfill film has low thermal conductivity and high thermal resistance, it may pose a problem by deteriorating the heat dissipation characteristics of the stacked semiconductor device.

An alumina-based underfill film may have high viscosity in its liquid state. Accordingly, an alumina-based underfill film may interfere with the wetting of micro-bumps with respect to the bonding pads during the bonding process, and due to such interference, the micro-bumps may not be bonded to the pads.

According to some example embodiments of the inventive concepts, an underfill film may include a first film layer having a first dielectric constant, and a second film layer on the first film layer and having a second dielectric constant, where the second dielectric constant is higher than the first dielectric constant.

According to some example embodiments of the inventive concepts, an underfill film may include a first film layer including a first thermosetting resin and a first inorganic filler, and a second film layer on the first film layer and including a second thermosetting resin and a second inorganic filler, where the first film layer has a first dielectric constant, where the second film layer has a second dielectric constant, and where the second dielectric constant is higher than the first dielectric constant.

According to some example embodiments of the inventive concepts, a semiconductor package may include a first semiconductor die, a second semiconductor die on the first semiconductor die, a plurality of connection members between the first semiconductor die and the second semiconductor die, and an underfill film between the first semiconductor die and the second semiconductor die, where the underfill film may be configured to surround the plurality of connection members, where the underfill film may include a first film layer having a first dielectric constant, and a second film layer on the first film layer and having a second dielectric constant, where the second dielectric constant is higher than the first dielectric constant.

An underfill film having a first film layer having a first dielectric constant and a second film layer on the first film layer and having a second dielectric constant higher than the first dielectric constant may be provided.

Accordingly, the first film layer may improve the wetting of micro-bumps to the bonding pads.

By including a second film layer having high thermal conductivity in the underfill film, in addition to the first film layer, low thermal resistance, and high viscosity, heat dissipation characteristics may be improved, fillet formation may be reduced, and problems of micro-bumps being short-circuited may be addressed. Accordingly, a semiconductor package may have reduced defects, and thus may have improved reliability, based on including the underfill film (e.g., between adjacent semiconductor dies of the semiconductor package).

### BRIEF DESCRIPTION OF THE DRAWINGS

FIG. 1 is a cross-sectional view showing a semiconductor package according to some example embodiments.

FIG. 2 is an enlarged cross-sectional view of the region A of FIG. 1 according to some example embodiments.

FIG. 3 is a cross-sectional view showing a semiconductor package according to some example embodiments.

FIG. 4 is a cross-sectional view showing an underfill film according to some example embodiments.

FIGS. 5, 6, 7, 8, 9, 10, 11, 12, 13, and 14 are cross-sectional views for explaining a method of stacking the semiconductor dies by using the underfill film of FIG. 4 according to some example embodiments.

### DETAILED DESCRIPTION

The present inventive concepts will be described more fully hereinafter with reference to the accompanying drawings, in which some example embodiments of the inventive concepts are shown. As those skilled in the art would realize, the described example embodiments may be modified in various different ways, all without departing from the spirit or scope of the present inventive concepts.

The drawings and description are to be regarded as illustrative in nature and not restrictive. Like reference numerals designate like elements throughout the specification.

Further, in the drawings, the size and thickness of each element are arbitrarily illustrated for ease of description, and the present inventive concepts are not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances.

Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Hereinafter, with reference to the drawings, an underfill film 140 a semiconductor package 100 including the underfill film 140, a semiconductor package 200 including the underfill film 140, and a method of stacking semiconductor dies by using the underfill film 140 will be described.

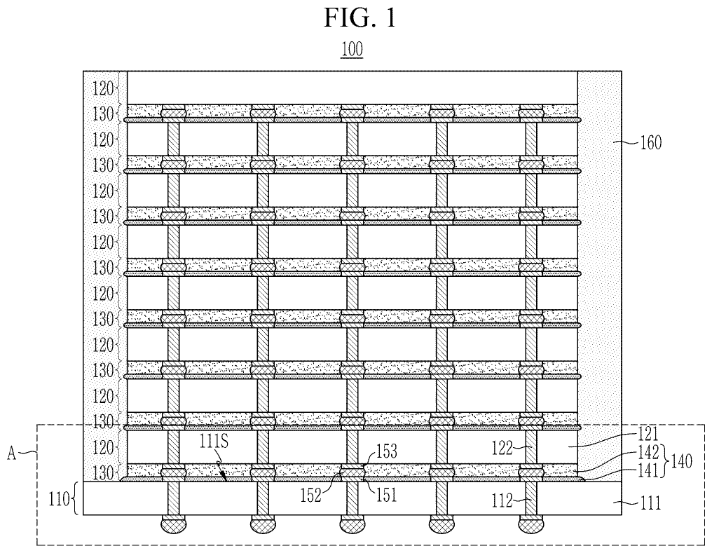

FIG. 1 is a cross-sectional view showing the semiconductor package 100 according to some example embodiments.

Referring to FIG. 1, the semiconductor package 100 may be a high bandwidth memory (HBM) 100. The high bandwidth memory (HBM) 100 may include a buffer die (base die; base logic die) 110, semiconductor dies (memory die; core die) 120, interconnection structures 130 alternating with the semiconductor dies 120, and a molding material 160. The high bandwidth memory (HBM) 100 according to the present inventive concepts may include a semiconductor stack in which eight semiconductor dies 120 are stacked, but example embodiments are not limited thereto, and in some example embodiments the high bandwidth memory (HBM) 100 may include a semiconductor stack in which the semiconductor dies 120 are stacked in various quantities. For example, the high bandwidth memory (HBM) 100 may include a semiconductor stack in which semiconductor dies of four, twelve, sixteen, twenty-four, or other quantities are stacked.

The high bandwidth memory (HBM) 100 may be a high performance 3D stack dynamic random-access memory (DRAM). The high bandwidth memory (HBM) 100 may be manufactured by using a technology of through-silicon vias (TSV) 112 and 122, in which each semiconductor stack is formed by vertically stacking the semiconductor dies 120 including a DRAM circuit, several thousands of fine holes vertically penetrating the stacked semiconductor dies 120 are formed in the semiconductor dies 120, and the holes are filled with a conductive material.

The high bandwidth memory (HBM) 100 may implement shorter latency and higher bandwidth compared to conventional DRAM products by having multiple memory channels by using a semiconductor stack manufactured by stacking semiconductor dies 120 vertically, while reducing the total area occupied by individual DRAMs on a printed circuit board (PCB), which is advantageous for high bandwidth to area and may reduce power consumption.

The buffer die 110 may be disposed lowermost in the high bandwidth memory (HBM) 100, and may be disposed between the stacked semiconductor dies 120 and external device (not shown). The buffer die 110 may include a buffer die base 111 and the through-silicon vias 112 within the buffer die base 111. The buffer die base 111 may comprise silicon. The semiconductor dies 120 may be disposed on the buffer die 110. The semiconductor dies 120 each may include a semiconductor die base 121 and one or more through-silicon vias 122 within the semiconductor die base 121. In some example embodiments, the semiconductor die base 121 may comprise silicon. In some example embodiments, the semiconductor die 120 may be a DRAM.

To implement higher bandwidth relative to area, it is advantageous to stack as many semiconductor dies 120 as possible on the buffer die 110. However, as the semiconductor dies 120 are stacked, surface topography may accumulate, causing the semiconductor dies 120 to become misaligned horizontally (e.g., in a direction parallel to an upper surface 111s of the buffer die base 111), and this may deteriorate etch uniformity during the subsequent through-silicon via forming process, cause bonding defects during the flip chip bonding process, and as a result, may lead to significant yield loss.

To stack as many semiconductor dies 120 as possible on the buffer die 110, the interconnection structure 130 may have a configuration that physically and electrically connects the buffer die 110 and the semiconductor die 120, or the semiconductor dies 120 to each other. Each of the interconnection structures 130 may be disposed between the buffer die 110 and the semiconductor die 120, or between the neighboring (e.g., adjacent) semiconductor dies 120 among the semiconductor dies 120.

Each of the interconnection structures 130 may include the underfill film 140, first bonding pads 151, connection members 152, and second bonding pads 153.

The underfill film 140 may be disposed between (e.g., directly between) the buffer die 110 and its neighboring semiconductor die 120, or between (e.g., directly between) neighboring semiconductor dies 120 (e.g., adjacent semiconductor dies 120). The underfill film 140 may surround and protect the first bonding pads 151, the connection members 152, and the second bonding pads 153. The underfill film 140 may bond the buffer die 110 and its neighboring semiconductor die 120, or bond neighboring semiconductor dies 120. The underfill film 140 may include a first film layer 141 and a second film layer 142. In some example embodiments, the underfill film 140 may be referred to as a non-conductive film (NCF). In some example embodiments, the first film layer 141 may include a silica-based inorganic filler. In some example embodiments, the second film layer 142 may include an alumina-based inorganic filler.

The first bonding pads 151, the connection members 152, and the second bonding pads 153 within each of the interconnection structures 130 may be disposed between (e.g., directly between) the buffer die 110 and its neighboring semiconductor die 120, or between (e.g., directly between) neighboring semiconductor dies 120. Each of the first bonding pads 151 may be disposed between each of the connection members 152 and each of the through-silicon vias 112 and 122. Each of the first bonding pads 151 may electrically connect each of the connection members 152 to each of the through-silicon vias 112 and 122. Each of the connection members 152 may be disposed between each of the first bonding pads 151 and each of the second bonding pads 153. Each of the connection members 152 may electrically connect each of the second bonding pads 153 to each of the first bonding pads 151. Each separate second bonding pad of the second bonding pads 153 may be disposed between one of the connection members 152 and one through-silicon via of the through-silicon vias 112 and 122. Each separate second bonding pad of the second bonding pads 153 may electrically connect one through-silicon via of the through-silicon vias 112 and 122 to one of the connection members 152. In some example embodiments, the first bonding pads 151 and the second bonding pads 153 may each include at least one of copper, aluminum, tungsten, nickel, gold, tin, titanium or any alloy thereof, respectively. In some example embodiments, the connection members 152 may include a micro-bump. In some example embodiments, the connection members 152 may each include at least one of tin, silver, lead, nickel, copper, or any alloy thereof.

The molding material 160 may be disposed on the buffer die 110, and may cover the semiconductor dies 120 and underfill films 140. The molding material 160 may serve (e.g., may be configured) to protect and insulate the semiconductor dies 120 and the underfill films 140. In some example embodiments, the molding material 160 may be an epoxy molding compound (EMC).

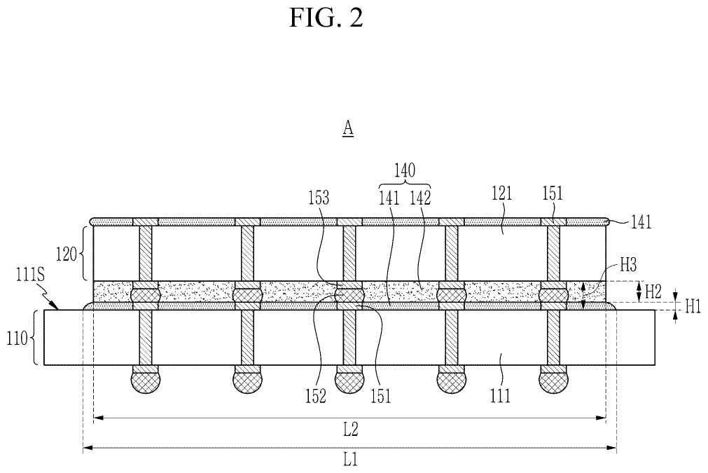

FIG. 2 is an enlarged cross-sectional view of the region A of FIG. 1 according to some example embodiments.

Referring to FIG. 2, the underfill film 140 may be disposed between (e.g., directly between) the buffer die 110 and the semiconductor die 120. The content of the underfill film 140 shown in and described with reference to FIG. 2 (e.g., the content, material composition, and/or structure of the underfill film 140) may be equally applied to some or all of the underfill films 140 disposed between neighboring semiconductor dies 120 as further shown in FIG. 1. The underfill film 140 may include the first film layer 141 and the second film layer 142.

The first film layer 141 may include at least one of a first thermosetting resin, a first curing agent, a first catalyst, a first flux, a first thermoplastic resin, or a first inorganic filler.

The first thermosetting resin may be (and/or may be included in) an underfill film disposed between the buffer die 110 and the semiconductor die 120, and may be selected from materials having appropriate thermal or mechanical properties. In some example embodiments, the first thermosetting resin may include an epoxy resin. In some example embodiments, epoxy resin may include at least one of a bisphenol-type epoxy resin or a novolac-type epoxy resin.

The first curing agent may be added to (e.g., included in) the first thermosetting resin, to cure the first thermosetting resin. The first curing agent may be added to adjust the curing level of the first thermosetting resin (e.g., proportion of the first thermosetting resin that is cured, amount of the first thermosetting resin that is cured, a magnitude of curing of the first thermosetting resin, etc.). One or more mechanical properties of the first film layer 141 may be adjusted by adding the first curing agent into the first thermosetting resin. In some example embodiments, the first curing agent may include at least one of an amine-based compound, an acid anhydride-based compound, an amide-based compound, an imidazole-based compound, or a phenol-based compound.

The first catalyst may be added to the first thermosetting resin, to adjust a curing rate of the first thermosetting resin. The curing rate of the first thermosetting resin (e.g., a rate at which the first thermosetting resin cures) may be adjusted according to the content of the first catalyst (e.g., an amount of the first catalyst in the first thermosetting resin or the first film layer 141, a proportional amount of the first catalyst in the first thermosetting resin or the first film layer 141, as a proportion of a total mass and/or volume of the first thermosetting resin or the first film layer 141, etc.), or adjusted by using the first catalyst for slowing down the curing rate. In some example embodiments, the first catalyst may include at least one of a phosphorus-based compound, a boron-based compound, a phosphorus-boron-based compound, or an imidazole-based compound.

The first flux may improve the wetting of the connection member 152 to the first bonding pad 151. The first flux may be selectively added to the first film layer 141. In some example embodiments, the first flux may include at least one of carboxylic acid, phenol, or amine.

The first thermoplastic resin may increase flowability of the first film layer 141 at a temperature (reflow temperature) at which the flip chip bonding is performed, to facilitate bonding of the first bonding pad 151 and the connection member 152. The first thermoplastic resin may decrease the thermal stress and mechanical stress between the buffer die 110 and the semiconductor die 120. In some example embodiments, the first thermoplastic resin may include at least one of polyimide-based resin, polyether imide-based resin, polyester imide-based resin, polyamide-based resin, polyether sulfone-based resin, polyether ketone-based resin, polyolefin-based resin, polyvinyl chloride-based resin, phenoxy-based resin, butadiene rubber, styrene-butadiene rubber, modified butadiene rubber, reactivity butadiene acrylonitrile copolymer rubber, butadiene acrylonitrile copolymer rubber, or acrylate-based resin.

The first inorganic filler may use (e.g., may include) a material having a lower dielectric constant (Low K) compared to a second inorganic filler. By adding the first inorganic filler into the first film layer 141, the first film layer 141 showing low viscosity characteristics (e.g., having lower viscosity than the second film layer 142) may be formed. Accordingly, the wetting of the connection member 152 to the first bonding pad 151 may be improved, and reliability of bonding between the first bonding pad 151 and the connection member 152 may be improved, such that the reliability of bonding between adjacent semiconductor dies 120, or between a semiconductor die 120 and the buffer die 110, by an interconnection structure 130 may be improved. Therefore, the reliability and functionality of the semiconductor package 100 may be improved due to including an interconnection structure 130 that further includes an underfill film 140 further having the first and second film layers 141 and 142 according to some example embodiments. In some example embodiments, the first inorganic filler may include silica (e.g., silica particles). In some example embodiments, the size of silica (e.g., a particle diameter of silica particles included in the first film layer 141) may be from about 50 nm to about 5 μm (e.g., the particle diameter of the silica particles may be between about 50 nm and about 5 μm). In some example embodiments, the content of silica (e.g., a silica content of the first film layer 141, or amount of silica in the first film layer 141, as a proportion of the total weight or mass of the first film layer 141) may be from about 20 wt % to about 60 wt % (e.g., as a proportion of the total weight of the first film layer 141). In some example embodiments, the silica content of the first inorganic filler, or amount of silica in the first inorganic filler, as a proportion of the total weight or mass of the first inorganic filler, may be from about 20 wt % to about 60 wt % (e.g., as a proportion of the total weight of the first inorganic filler). The viscosity of the first film layer 141 may be finely adjusted by adjusting the size (e.g., particle diameter) of silica and the content of silica (e.g., a silica content of the first film layer 141 as a proportion of the total weight or mass of the first film layer 141, a silica content of the first inorganic filler as a proportion of the total weight or mass of the first inorganic filler, or the like) within the above-described ranges.

If the size of silica becomes greater, or the content of silica is reduced, the viscosity of the first film layer 141 may decrease. The viscosity of the first film layer 141 may mean a minimum viscosity. In some example embodiments, the minimum viscosity of the first film layer 141 may be from about 100 Pa·s to about 3,000 Pa·s. In some example embodiments, a minimum viscosity temperature of the first film layer 141 may be from about 120° C. to about 160° C.

The second film layer 142 may include at least one of a second thermosetting resin, a second curing agent, a second catalyst, a second flux, a second thermoplastic resin, or the second inorganic filler.

The second thermosetting resin may be (and/or may be included in) an underfill film disposed between the buffer die 110 and the semiconductor die 120, and may be selected from materials having appropriate thermal or mechanical properties. In some example embodiments, the second thermosetting resin may include an epoxy resin. In some example embodiments, epoxy resin may include at least one of a bisphenol-type epoxy resin or a novolac-type epoxy resin.

The second curing agent may be added to (e.g., included in) the second thermosetting resin, to cure the second thermosetting resin. The second curing agent may be added to adjust the curing level of the second thermosetting resin (e.g., proportion of the second thermosetting resin that is cured, amount of the second thermosetting resin that is cured, a magnitude of curing of the second thermosetting resin, etc.). One or more mechanical properties of the second film layer 142 may be adjusted by adding the second curing agent into the second thermosetting resin. In some example embodiments, the second curing agent may include at least one of an amine-based compound, an acid anhydride-based compound, an amide-based compound, an imidazole-based compound, or a phenol-based compound.

The second catalyst may be added to the second thermosetting resin, to adjust a curing rate of the second thermosetting resin. The curing rate of the second thermosetting resin (e.g., a rate at which the second thermosetting resin cures) may be adjusted according to the content of the second catalyst (e.g., an amount of the second catalyst in the second thermosetting resin or the second film layer 142, a proportional amount of the second catalyst in the second thermosetting resin or the second film layer 142, as a proportion of a total mass and/or volume of the second thermosetting resin or the second film layer 142, etc.), or adjusted by using the second catalyst for slowing down the curing rate. In some example embodiments, the second catalyst may include at least one of a phosphorus-based compound, a boron-based compound, a phosphorus-boron-based compound, or an imidazole-based compound.

The second flux may improve the wetting of the connection member 152 to the first bonding pad 151, thereby improving bonding of adjacent semiconductor dies 120, or a semiconductor die 120 and the buffer die 110 through at least the connection member 152 and the first bonding pad 151, provided by the interconnection structure 130, and thereby improving the reliability and thus functionality of a semiconductor package 100 based on the semiconductor package 100 including an interconnection structure 130 that further includes an underfill film 140 further having the first and second film layers 141 and 142 according to some example embodiments. The second flux may be selectively added to the second film layer 142. In some example embodiments, the second flux may include at least one of carboxylic acid, phenol, or amine.

The second thermoplastic resin may increase flowability of the second film layer 142 at a temperature (reflow temperature) at which the flip chip bonding is performed, to facilitate bonding of the first bonding pad 151 and the connection member 152. The second thermoplastic resin may decrease the thermal stress and mechanical stress between the buffer die 110 and the semiconductor die 120. In some example embodiments, the second thermoplastic resin may include at least one of polyimide-based resin, polyether imide-based resin, polyester imide-based resin, polyamide-based resin, polyether sulfone-based resin, polyether ketone-based resin, polyolefin-based resin, polyvinyl chloride-based resin, phenoxy-based resin, butadiene rubber, styrene-butadiene rubber, modified butadiene rubber, reactivity butadiene acrylonitrile copolymer rubber, butadiene acrylonitrile copolymer rubber, or acrylate-based resin.

The second inorganic filler may use (e.g., may include) a material having a higher dielectric constant (High K) compared to the first inorganic filler. By adding the second inorganic filler having high dielectric constant (High K), heat dissipation characteristics of the semiconductor package 100 (e.g., configuration of the semiconductor package 100 to dissipate heat) may be improved, thereby improving reliability and functionality of the semiconductor package 100 based on reducing, minimizing, or preventing the likelihood of faults, defects, failures, or the like due to overheating in the semiconductor package 100. In addition, by adding the second inorganic filler into the second film layer 142, the second film layer 142 showing high viscosity characteristics (e.g., having greater viscosity than the first film layer 141) may be formed. Accordingly, the semiconductor package 100 may be prevented from forming the fillet therein, or the size of the formed fillet may be reduced or minimized, and the problem of the connection members 152 within the interconnection structure 130 being short-circuited may be reduced, minimized, or prevented, and therefore the reliability and functionality of the semiconductor package 100 may be improved based on including an interconnection structure 130 that includes the underfill film 140 having first and second film layers 141 and 142 according to some example embodiments. In some example embodiments, the second inorganic filler may include alumina (e.g., alumina particles). In some example embodiments, the size of alumina (e.g., a particle diameter of alumina particles included in the second film layer 142) may be from about 50 nm to about 5 μm (e.g., the particle diameter of the alumina particles may be between about 50 nm and about 5 μm). In some example embodiments, the content of alumina (e.g., an alumina content of the second film layer 142, or amount of alumina in the second film layer 142, as a proportion of the total weight or mass of the second film layer 142) may be from about 40 wt % to about 80 wt % (e.g., as a proportion of the total weight of the second film layer 142). In some example embodiments, the alumina content of the second organic filler, or amount of alumina in the second inorganic filler, as a proportion of the total weight or mass of the second inorganic filler, may be from about 40 wt % to about 80 wt % (e.g., as a proportion of the total weight of the second inorganic filler). The viscosity of the second film layer 142 may be finely adjusted by adjusting the size (e.g., particle diameter) of alumina and the content of alumina (e.g., an alumina content of the second film layer 142, as a proportion of the total weight or mass of the second film layer 142) within the above-described ranges.

If the size of alumina is decreased, the content of alumina is increased, viscosity of the second film layer 142 may increase. The viscosity of the second film layer 142 may mean a minimum viscosity. In some example embodiments, the minimum viscosity of the second film layer 142 may be from about 1,500 Pa·s to about 10,000 Pa·s. In some example embodiments, a minimum viscosity temperature of the second film layer 142 may be from about 100° C. to about 140° C.

The first film layer 141 may include silica having a relatively low dielectric constant (e.g., a lower dielectric constant than the alumina) as the first inorganic filler, and the second film layer 142 may include alumina having a relatively high dielectric constant (e.g., a greater dielectric constant than the silica) as the second inorganic filler. Based on such features, the first film layer 141 and the second film layer 142 of the underfill film 140 may be a composite film layer and have various mechanical properties. The first film layer 141 may have a first dielectric constant, and the second film layer 142 may have a second dielectric constant that is higher (e.g., greater) than the first dielectric constant. The first film layer 141 may have a first viscosity, and the second film layer 142 may have a second viscosity that is higher (e.g., greater) than the first viscosity. The first film layer 141 may have a first minimum viscosity, and the second film layer 142 may have a second minimum viscosity that is higher (e.g., greater) than the first minimum viscosity.

The first film layer 141 may include silica (e.g., silica particles) as the first inorganic filler, and the second film layer 142 may include alumina (e.g., alumina particles) as the second inorganic filler. Based on such features, the first film layer 141 and the second film layer 142 of the underfill film 140 may be a composite film layer and have various thermal properties. The first film layer 141 may have a first thermal conductivity, and the second film layer 142 may have a second thermal conductivity higher than the first thermal conductivity. In some example embodiments, the first thermal conductivity may be about 0.45 W/mK. In some example embodiments, the second thermal conductivity may be about 1 W/mK. The first film layer 141 may have a first thermal resistance, and the second film layer 142 may have a second thermal resistance lower than the first thermal resistance. In some example embodiments, a thermal resistance of the underfill film 140 may be from about 0.21° C./W to about 0.24° C./W.

The first film layer 141 may have a first thickness H1 in a vertical direction. The vertical direction may extend perpendicular to the upper surface 111s of the buffer die base 111. In some example embodiments, the first thickness H1 of the first film layer 141 may be from about 1 μm to about 19 μm. The second film layer 142 may have a second thickness H2 in the vertical direction. In some example embodiments, the second thickness H2 of the second film layer 142 may be from about 1 μm to about 19 μm. The underfill film 140 may have a third thickness H3 in the vertical direction. The third thickness H3 of the underfill film 140 may be a sum of the first thickness H1 and the second thickness H2. In some example embodiments, a thickness ratio of the first film layer 141 and the second film layer 142 in the vertical direction (e.g., a ratio of the first thickness H1 to the second thickness H2) may be from about 1:19 to about 19:1. The first film layer 141 may have a first width L1 in a horizontal direction. The horizontal direction may extend parallel to the upper surface 111s of the buffer die base 111. The second film layer 142 may have a second width L2 in the horizontal direction, which is smaller than the first width L1.

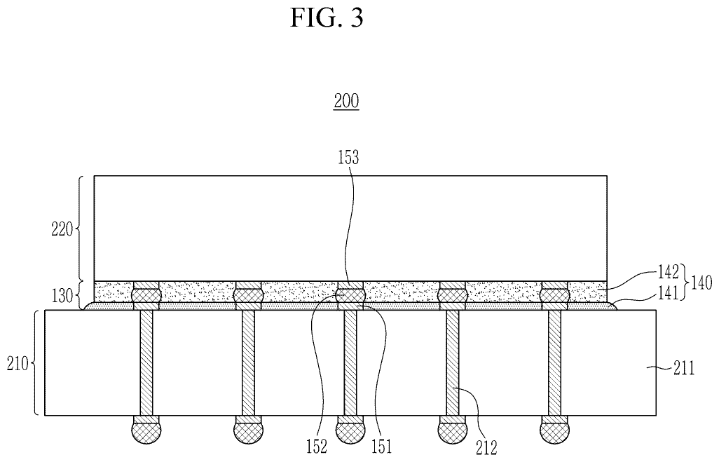

FIG. 3 is a cross-sectional view showing a semiconductor package 200 according to some example embodiments.

Referring to FIG. 3, the semiconductor package 200 is a 3D integrated circuit (3DIC) structure 200. The 3D integrated circuit (3DIC) structure 200 may include a first semiconductor die (lower semiconductor die) 210, the interconnection structure 130, and a second semiconductor die (upper semiconductor die) 220. The 3D integrated circuit (3DIC) structure 200 may be an integrated circuit that is implemented as 3-dimensional chip, which may be referred to as a technology that transitions the stacking method of semiconductor dies from the conventional horizontal method to a vertical method. By using the vertical stacking method, more devices can be implemented on the same silicon wafer area, which may lower manufacturing costs and enhance performance. In some example embodiments, the 3D integrated circuit (3DIC) structure 200 may be a chiplet stacking structure formed by stacking chiplets.

The first semiconductor die 210 may be disposed lowermost in the 3D integrated circuit (3DIC) structure 200. The first semiconductor die 210 may be manufactured by using a technology of through-silicon via (TSV) 212, in which fine holes vertically penetrating a first semiconductor die base 211 are formed within the first semiconductor die base 211, and the holes are filled with a conductive material. In some example embodiments, the first semiconductor die 210 may include at least one of a central processing unit (CPU) or a graphics processing unit (GPU).

The second semiconductor die 220 may be disposed on the first semiconductor die 210. In some example embodiments, the second semiconductor die 220 may include at least one of a memory, a communication chip, or a sensor.

The interconnection structure 130 may be disposed between the first semiconductor die 210 and the second semiconductor die 220. The first semiconductor die 210 (e.g., the first semiconductor die base 211) may comprise silicon. The second semiconductor die 220 may comprise silicon. The interconnection structure 130 may have a configuration that physically and electrically connects the first semiconductor die 210 and the second semiconductor die 220. Each of the interconnection structures 130 may include the underfill film 140, the first bonding pads 151, the connection members 152, and the second bonding pads 153. The content described with reference to the semiconductor package 100 of FIG. 1 and FIG. 2 may be equally applied to the interconnection structure 130, the underfill film 140, the first bonding pads 151, the connection members 152, and the second bonding pads 153.

In addition, the underfill film 140 may be applied to configurations based on the technology of various semiconductor packages, such as the stacking structure of package-on-package (POP), or fan-out wafer level package (FOWLP) or fan-out panel level package (FOPLP).

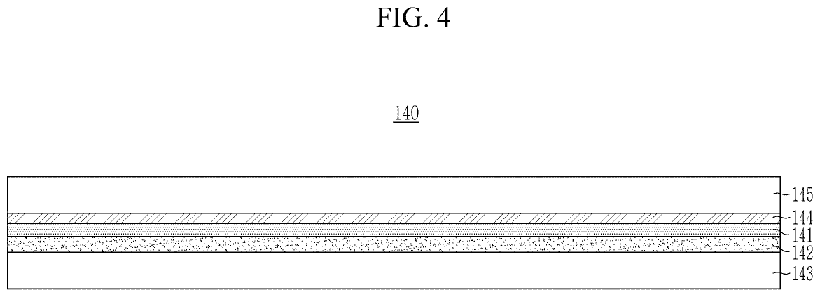

FIG. 4 is a cross-sectional view showing an underfill film 140 according to some example embodiments. FIG. 4 illustrates the underfill film 140 in the product state before being applied to a semiconductor package.

Referring to FIG. 4, the underfill film 140 may include a release film 143, the second film layer 142, the first film layer 141, a buffer layer 144, and a base film 145, from the bottom.

The release film 143 may be a support member of other layers of the underfill film 140. The release film 143 may be removed from the second film layer 142 by peeling. In some example embodiments, the release film 143 may include polyethylene terephthalate (PET). The second film layer 142 may be disposed on the release film 143. The first film layer 141 may be disposed on the second film layer 142. The buffer layer 144 may be disposed on the first film layer 141. The buffer layer 144 may function as a buffer. In some example embodiments, the buffer layer 144 may include a pressure-sensitive adhesive (PSA). The base film 145 may protect other layers of the underfill film 140. In some example embodiments, the base film 145 may include polyolefin. The buffer layer 144 and the base film 145 may be removed from the first film layer 141 by peeling.

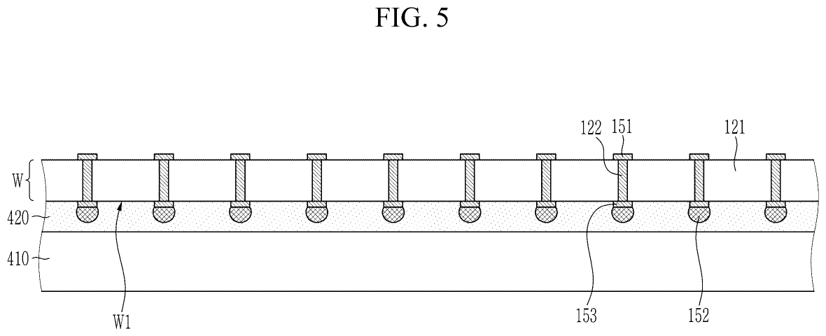

FIGS. 5, 6, 7, 8, 9, 10, 11, 12, 13, and 14 are cross-sectional views for explaining a method of stacking the buffer die 110 and the semiconductor die 120 of the high bandwidth memory (HBM) 100 by using the underfill film 140 of FIG. 4 according to some example embodiments. Such a stack method may also be applied to other stacking structures using the underfill film 140.

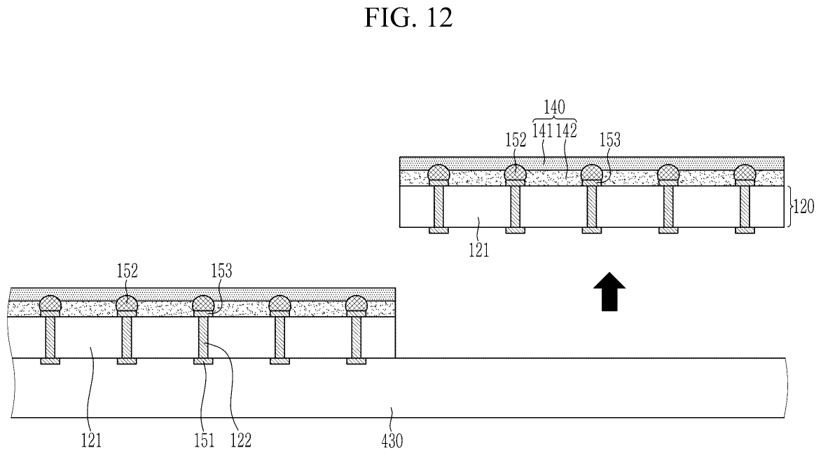

FIG. 5 is a cross-sectional view showing the step of providing a wafer W attached to a carrier 410 and including the semiconductor dies 120 (refer to FIG. 12).

Referring to FIG. 5, the wafer W including the semiconductor dies 120 may be provided. In some example embodiments, the wafer W may be replaced with a panel. The connection members 152 connected to through-silicon vias may be formed on a first surface W1 of the wafer W, a temporary adhesive 420 may be attached on the first surface W1 on which the connection members 152 are formed, and the carrier 410 may be attached to the temporary adhesive 420. The carrier 410 and the temporary adhesive 420 may be attached on the first surface W1 of the wafer W by performing a carrier bonding process of a wafer supporting system (WSS) process. The carrier 410 may include, for example, a silicon-based material such as glass or a silicon oxide, an organic material, or another material such as an aluminum oxide, a combination of these materials, or the like.

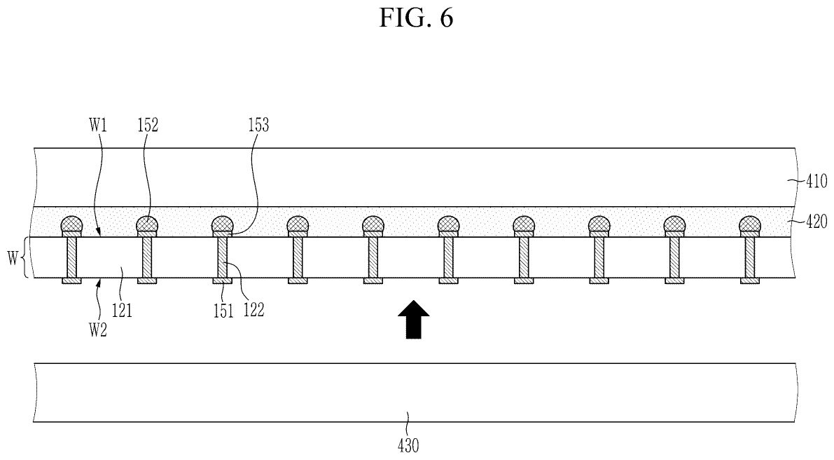

FIG. 6 is a cross-sectional view showing the step of attaching a dicing tape 430 on the wafer W including the semiconductor dies 120.

Referring to FIG. 6, the dicing tape 430 may be attached to a second surface W2 of the wafer W including the semiconductor dies 120. The second surface W2 may be an opposite surface of the first surface W1.

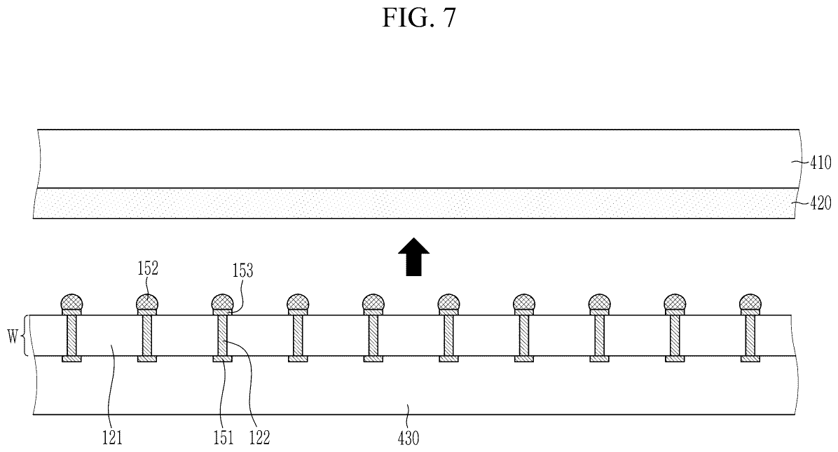

FIG. 7 is a cross-sectional view showing the step of removing the carrier 410 from the wafer W including the semiconductor dies 120.

Referring to FIG. 7, the carrier 410 may be removed from the wafer W including the semiconductor dies 120. The carrier 410 may be removed by performing a carrier debonding process of the WSS process. After removing the carrier 410, a cleaning process may be performed to remove the temporary adhesive 420.

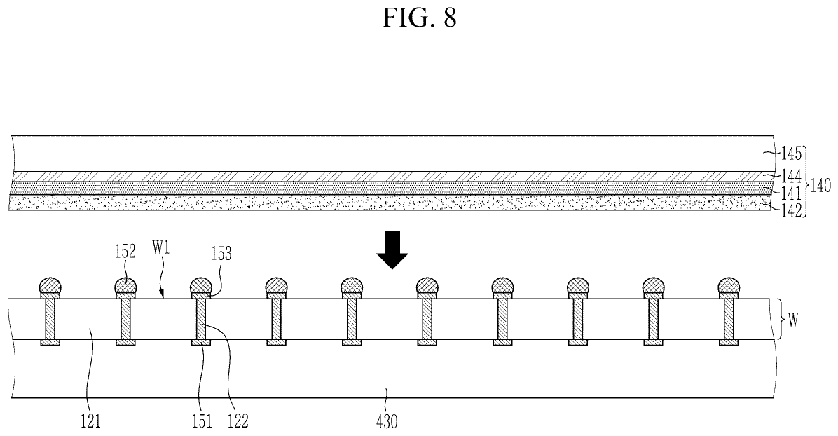

FIG. 8 is a cross-sectional view showing the step of aligning the underfill film 140 on (e.g., over) the first surface W1 of the wafer W including the semiconductor dies 120.

Referring to FIG. 8, the underfill film 140 may be aligned on the first surface W1 of the wafer W including the semiconductor dies 120. The underfill film 140, which is obtained by removing the release film 143 from the underfill film 140 of FIG. 4, may be provided.

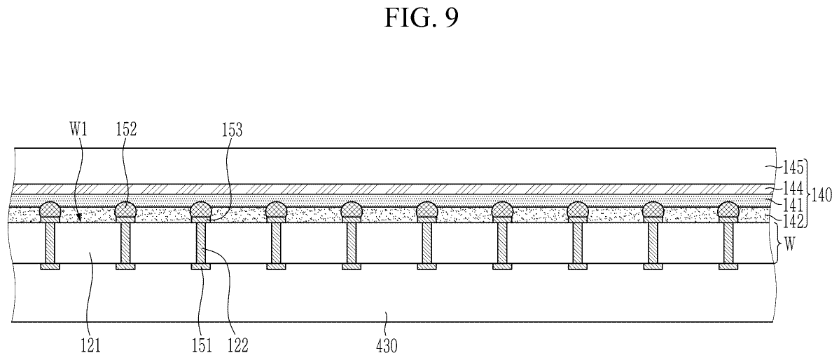

FIG. 9 is a cross-sectional view showing the step of attaching the underfill film 140 on the first surface W1 of the wafer W including the semiconductor dies 120.

Referring to FIG. 9, the underfill film 140 may be attached on the first surface W1 of the wafer W including the semiconductor dies 120. The first film layer 141 and the second film layer 142 of the underfill film 140 may penetrate the connection members 152 and the second bonding pads 153.

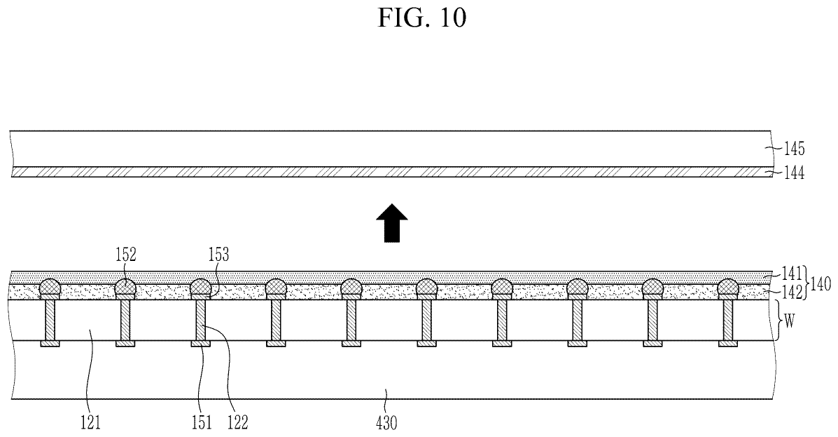

FIG. 10 is a cross-sectional view showing the step of removing the buffer layer 144 and the base film 145 from the underfill film 140.

Referring to FIG. 10, the buffer layer 144 and the base film 145 may be removed from the underfill film 140.

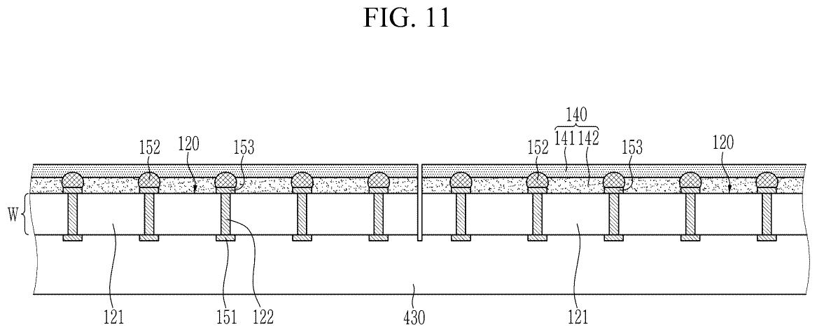

FIG. 11 is a cross-sectional view showing the step of singulating the wafer W including the semiconductor dies 120.

Referring to FIG. 11, the wafer W including the semiconductor dies 120 may be singulated into separate semiconductor dies 120. In some example embodiments, the singulation process may be performed by a laser or sawing process. After the singulation process, the wafer W may be separated into the semiconductor dies 120.

FIG. 12 is a cross-sectional view showing the step of separating the semiconductor dies 120 from the dicing tape 430.

Referring to FIG. 12, by irradiating ultraviolet rays on the dicing tape 430, the semiconductor dies 120 may be separated from the dicing tape 430.

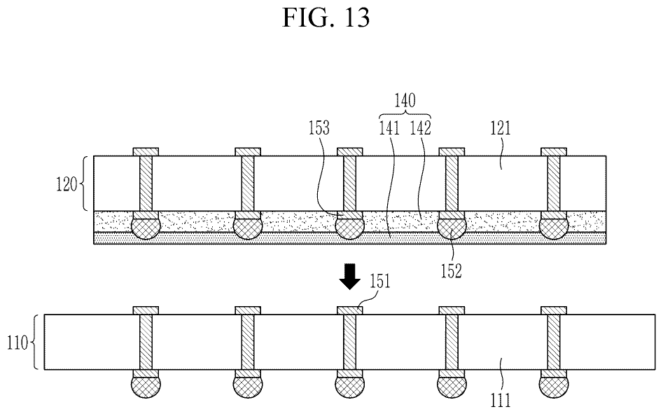

FIG. 13 is a cross-sectional view showing the step of aligning the semiconductor die 120 on the buffer die 110.

Referring to FIG. 13, the semiconductor die 120 may be aligned on (e.g., over) the buffer die 110.

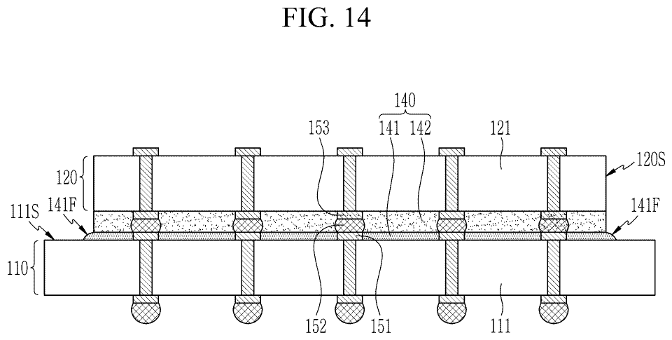

FIG. 14 is a cross-sectional view showing the step of bonding the buffer die 110 and the semiconductor die 120.

Referring to FIG. 14, the buffer die 110 and the semiconductor die 120 may be bonded. In some example embodiments, the buffer die 110 and the semiconductor die 120 may be bonded by a thermal compression (TC) process. The underfill film 140 may be in a gel state before performing the thermal compression process, may change from the gel state to a liquid state by being heated while performing the thermal compression process, and finally achieve the cured state (e.g., based on such heating while performing the thermal compression process). The first film layer 141 may have a first curing rate. The second film layer 142 may have a second curing rate faster than the first curing rate. The underfill film 140 may be attached between the buffer die 110 and the semiconductor die 120, and the first bonding pads 151. The underfill film 140 may protect (e.g., encapsulate and isolate from an exterior of the semiconductor package 100) connection members 152, and the second bonding pads 153. Although the first film layer 141 of a low viscosity may form a fillet 141F, which may include a portion of the underfill film 140 (e.g., a portion of the first film layer 141 as shown) extending (e.g., protruding) outward beyond the sidewalls 120S of the semiconductor die 120 in a horizontal direction parallel to the upper surface 111s of the buffer die base 111, the second film layer 142 of a high viscosity is located on the first film layer 141, and excessive formation of the fillet 141F may be reduced, minimized, or prevented, such that a size of any formed fillet 141F may be reduced or minimized.

While the inventive concepts have been described in connection with what is presently considered to be practical example embodiments, it is to be understood that the inventive concepts are not limited to such example embodiments, but, on the contrary, are intended to cover various modifications and equivalent arrangements included within the spirit and scope of the appended claims.

What is claimed is:

1. An underfill film, comprising:
a first film layer having a first dielectric constant; and
a second film layer on the first film layer, the second film layer having a second dielectric constant,
wherein the second dielectric constant is higher than the first dielectric constant.

2. The underfill film of claim 1, wherein:
the first film layer has a first viscosity;
the second film layer has a second viscosity; and
the second viscosity is higher than the first viscosity.

3. The underfill film of claim 1, wherein:
a minimum viscosity of the first film layer is from about 100 Pa·s to about 3,000 Pa·s; and
a minimum viscosity of the second film layer is from about 1,500 Pa·s to about 10,000 Pa·s.

4. The underfill film of claim 3, wherein:
a minimum viscosity temperature of the first film layer is from about 120° C. to about 160° C.; and
a minimum viscosity temperature of the second film layer is from about 100° C. to about 140° C.

5. The underfill film of claim 1, wherein:
the first film layer has a first thermal conductivity;
the second film layer has a second thermal conductivity; and
the second thermal conductivity is higher than the first thermal conductivity.

6. The underfill film of claim 1, wherein:
the first film layer has a first thermal resistance;
the second film layer has a second thermal resistance; and
the second thermal resistance is lower than the first thermal resistance.

7. An underfill film, comprising:
a first film layer, the first film layer including a first thermosetting resin and a first inorganic filler; and
a second film layer on the first film layer, the second film layer including a second thermosetting resin and a second inorganic filler,
wherein the first film layer has a first dielectric constant,
wherein the second film layer has a second dielectric constant, and
wherein the second dielectric constant is higher than the first dielectric constant.

8. The underfill film of claim 7, wherein:
the first inorganic filler comprises silica.

9. The underfill film of claim 8, wherein a particle diameter of the silica is from about 50 nm to about 5 μm.

10. The underfill film of claim 8, wherein a silica content of the first film layer is from about 20 wt % to about 60 wt % as a proportion of a total weight of the first film layer.

11. The underfill film of claim 7, wherein the second inorganic filler comprises alumina.

12. The underfill film of claim 11, wherein a particle diameter of the alumina is from about 50 nm to about 5 μm.

13. The underfill film of claim 11, wherein an alumina content of the second film layer is from about 40 wt % to about 80 wt % as a proportion of a total weight of the second film layer.

14. The underfill film of claim 7, wherein the first film layer further comprises flux.

15. The underfill film of claim 7, wherein the first film layer and the second film layer each comprise at least one of a curing agent, a catalyst, or a thermoplastic resin.

16. The underfill film of claim 7, wherein the first thermosetting resin and the second thermosetting resin each comprise epoxy.

17. A semiconductor package, comprising:
a first semiconductor die;
a second semiconductor die on the first semiconductor die;
a plurality of connection members between the first semiconductor die and the second semiconductor die; and
an underfill film between the first semiconductor die and the second semiconductor die, the underfill film configured to surround the plurality of connection members,
wherein the underfill film includes
a first film layer having a first dielectric constant, and
a second film layer on the first film layer, the second film layer having a second dielectric constant,
wherein the second dielectric constant is higher than the first dielectric constant.

18. The semiconductor package of claim 17, wherein a thickness ratio of the first film layer and the second film layer in a vertical direction is from about 1:19 to about 19:1.

19. The semiconductor package of claim 17, wherein a thickness of each of the first film layer and the second film layer in a vertical direction is from about 1 μm to about 19 μm.

20. The semiconductor package of claim 17, wherein a thermal resistance of the underfill film is from about 0.21° C./W to about 0.24° C./W.
